(19) United States
(12) Patent Application Publication
(10) Pub. No.: US 2012/0007106 A1
(43) Pub. Date: Jan. 12, 2012

(54) ORGANIC LIGHT EMITTING DIODE DISPLAY

(75) Inventors: Woo-Suk Jung, Yongin-city (KR); Soon-Ryong Park, Yongin-city (KR); Hye-Jung Park, Yongin-city (KR)

(73) Assignee: SAMSUNG MOBILE DISPLAY CO., LTD., Yongin-City (KR)

(21) Appl. No.: 13/033,311

(22) Filed: Feb. 23, 2011

(30) Foreign Application Priority Data
Jul. 7, 2010 (KR) 10-2010-0065568

(51) Int. Cl. H01L 51/52

(52) U.S. Cl. 257/88; 257/E51.018

(57) ABSTRACT

An organic light emitting diode (OLED) display according to an exemplary embodiment includes an organic light emitting display panel that includes an organic light emitting member, a polarizing plate that is spaced-apart from the organic light emitting display panel and arranged at an upper portion thereof, and a window that is attached to an upper portion of the polarizing plate and protects the organic light emitting display panel. The polarizing plate may include a linear polarizing member and a retardation film that is disposed under the linear polarizing member. According to the exemplary embodiment, the external light visibility can be improved by absorbing light that is incident on the lower portion of the polarizing plate by the polarizing plate by attaching the polarizing plate to the lower portion of the window and separating the polarizing plate from the organic light emitting display panel.

### CLAIM OF PRIORITY

This application makes reference to, incorporates the same herein, and claims all benefits accruing under 35 U.S.C. §119 from an application for ORGANIC LIGHT-EMITTING DIODE DISPLAY, earlier filed in the Korean Intellectual Property Office on 7 Jul. 2010 and there duly assigned Serial No. 10-2010-0065568.

### BACKGROUND OF THE INVENTION

1. Field of the Invention

The described technology relates generally to an organic light emitting diode (OLED) display.

2. Description of the Related Art

An organic light emitting diode (OLED) display includes two electrodes and an organic emission layer that is disposed between them. Electrons that are injected from one electrode and holes that are injected from the other electrode are recombined with the organic emission layer to form an exciton that emits light when the exciton discharges energy.

### SUMMARY OF THE INVENTION

The described technology has been made in an effort to provide an organic light emitting diode (OLED) display that can improve the external light visibility, implement cost reduction and process simplification, and protect the organic light emitting display panel from external impact upon being dropped.

According to an aspect of the present invention, there is provided an organic light emitting diode (OLED) display that includes an organic light emitting display panel that includes an organic light emitting member, a polarizing plate spaced-apart from the organic light emitting display panel and arranged at an upper portion thereof and a window that is attached to an upper portion of the polarizing plate to protect the organic light emitting display panel. The polarizing plate may include a linear polarizing member and a retardation film arranged under the linear polarizing member. The retardation film may be a λ/4 retardation film. The OLED display may also include a first adhesive layer that is arranged between the linear polarizing member and the window. The display may also include a second adhesive layer arranged between the linear polarizing member and the λ/4 retardation film. The display may also include a protective film that is attached to a lower portion of the λ/4 retardation film. The organic light emitting display panel may also include a reflection electrode. The external light may be reflected off the reflection electrode and be absorbed by the polarizing plate. The polarizing plate may be in direct contact with said window.

The display may be adapted to allow the external light to pass through the window and the polarizing plate from an outside, reflect of the reflection electrode of the organic light emitting display panel, and then convert the external light from a circularly polarized light to a linearly polarized light by passing through the retardation film of the polarizing plate for a second time, the linearly polarized external light then being absorbed by the linear polarizing member of the polarizing plate. The linearly polarized external light may have a polarization axis that is orthogonal to a penetration axis of the linear polarizing member of the polarizing plate after said passing through the retardation film for said second time.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an organic light emitting diode (OLED) display according to an exemplary embodiment;

FIG. 2 is a cross-sectional view that illustrates the polarizing plate of FIG. 1 in detail;

FIG. 3 is an equivalent circuit of an organic light emitting diode (OLED) display according to an exemplary embodiment; and

FIG. 4 is a schematic diagram that illustrates an operation principle of the organic light emitting diode (OLED) display of FIG. 1.

### DETAILED DESCRIPTION OF THE INVENTION

The organic light emitting diode (OLED) display includes an organic light emitting display panel that displays an image and a window that is spaced-apart from the organic light emitting display panel by a gap in order to protect the organic light emitting display module. However, since light that is generated in the organic light emitting display panel is emitted to the outside through the gap, the contrast ratio, the external light visibility in respect to the contrast ratio and the color reproduction range under external light deteriorate due to a difference between the refractive indexes of the window and the gap and the deterioration of the transmittance by the gap. In addition, since the external light reflects on the window surface and the polarizing plate surface of the organic light emitting display panel, the external visibility is further deteriorated.

In order to reduce the deterioration of the external light visibility, an organic light emitting diode (OLED) display can be designed to have a window integrated structure in which an adhesive agent or a resin is filled between the window and the organic light emitting display panel. The polarizing plate may then be attached to the outermost portion thereof.

However, the organic light emitting diode (OLED) display having the window integrated structure can solve the problem of the deterioration due to the refractive index and due to the transmittance of the gap and can improve the external light visibility by lowering the reflectance in respects to the lower surface of the window and the polarizing plate surface. However, with such a design, a problem of an increase of cost may occur due to the low process yield, the separate process line and expensive equipment. In addition, in the organic light emitting diode (OLED) display that has the window integrated structure, since the adhesive agent is filled between the organic light emitting display panel and the window, for an instantaneous impact in a local area by falling, it may be difficult to protect the organic light emitting display panel from damage.

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification. In addition, the size and thickness of each component shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thickness of some layers and areas are exaggerated.

It will be understood that when an element, such as a layer, film, region, or substrate, is referred to as being “on” another element, it can be directly on the other element or intervening elements may also be present.

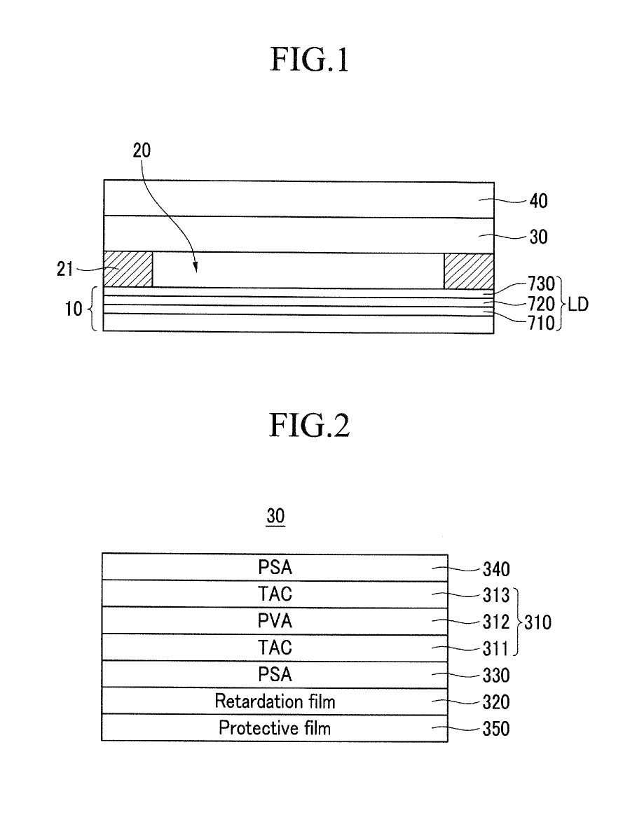

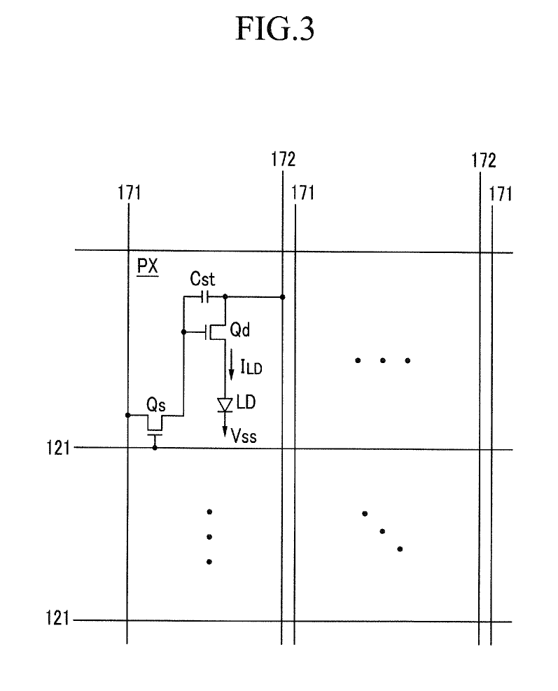

Hereinafter, an organic light emitting diode (OLED) display according to an exemplary embodiment will be described in detail with reference to FIGS. 1 through 3. FIG. 1 is a cross-sectional view of an organic light emitting diode (OLED) display according to an exemplary embodiment, FIG. 2 is a cross-sectional view that illustrates the polarizing plate of FIG. 1 in detail, and FIG. 3 is an equivalent circuit of an organic light emitting diode (OLED) display according to an exemplary embodiment.

As shown in FIGS. 1 through 3, the organic light emitting diode (OLED) display according to an exemplary embodiment includes an organic light emitting display panel 10 that illustrates an image, a polarizing plate 30 that is spaced-apart separated from the organic light emitting display panel 10 and disposed thereon, and a window 40 of transparent material that is attached to an upper portion of the polarizing plate 30.

First, the internal construction of the organic light emitting display panel 10 will now be described in detail in conjunction with FIG. 3. As shown in FIG. 3, the organic light emitting display panel 10 includes a plurality of signal lines 121, 171, and 172 and a plurality of pixels PX that are connected thereto and arranged in an approximate matrix form.

The signal lines 121, 171, and 172 include a plurality of gate lines 121 that transfer the gate signal (or scan signal), a plurality of data lines 171 that transfer the data signal, and a plurality of driving voltage lines 172 that transfer the driving voltage. The gate line 121 extends in an approximate row direction and are parallel to each other, and the data line 171 and the driving voltage line 172 extend in an approximate column direction and are almost parallel to each other.

Each pixel PX includes a switching thin film transistor Qs, a driving thin film transistor Qd, storage capacitor Cst and an organic light emitting diode (OLED) LD. The switching thin film transistor Qs has a control terminal, an input terminal and an output terminal. The control terminal is connected to the gate line 121, the input terminal is connected to the data line 171, and the output terminal is connected to the driving thin film transistor Qd. The switching thin film transistor Qs is activated in response to the scan signal that is applied by the gate line 121 so that the data signal that is applied to the data line 171 can be transferred to the driving thin film transistor Qd.

The driving thin film transistor Qd also has a control terminal, an input terminal and an output terminal. The control terminal is connected to the output terminal of the switching thin film transistor Qs, the input terminal is connected to the driving voltage line 172, and the output terminal is connected to the organic light emitting diode (OLED) LD. The driving thin film transistor Qd allows for the passage of output current ILD, whose magnitude varies according to the voltage that is applied between the control terminal and the output terminal.

The capacitor Cst is connected between the control terminal and input terminal of the driving thin film transistor Qd. This capacitor Cst charges the data signal applied to the control terminal of the driving thin film transistor Qd and maintains the data signal after the switching thin film transistor Qs is turned off.

The organic light emitting diode (OLED) LD has an anode that is connected to the output terminal of the driving thin film transistor Qd and a cathode that is connected to the common voltage Vss. The organic light emitting diode (OLED) LD displays an image by emitting light while the intensity thereof is changed according to the output current ILD of the driving thin film transistor Qd.

The switching thin film transistor Qs and the driving thin film transistor Qd may be n-channel field effect transistors (FETs), however the present invention is in now way so limited as at least one of the switching thin film transistor Qs and the driving thin film transistor Qd may instead be a p-channel FET. In addition, the connection relation of the thin film transistors Qs, and Qd, the capacitor Cst and the organic light emitting diode (OLED) LD may be changed.

In FIG. 1, in the organic light emitting display panel 10, only the pixel electrode 710 that corresponds to the anode, the common electrode 730 that corresponds to the cathode and the organic light emitting member 720 that is formed between the anode and the cathode are illustrated.

As shown in FIG. 1, the pixel electrode 710, the organic light emitting member 720 and the common electrode 730 form the organic light emitting diode (OLED) LD. In the case of the top light emitting type display, the pixel electrode 710 may include a transparent material such as ITO (Indium Tin Oxide) or IZO (Indium Zinc Oxide), and a separate reflection electrode that has a high reflection ratio may be formed thereon. The reflection electrode may be made out of reflective material such as lithium (Li), calcium (Ca), lithium fluoride/calcium (LiF/Ca), lithium fluoride/aluminum (LiF/Al), aluminum (Al), silver (Ag), magnesium (Mg), or gold (Au) may be used.

The organic light emitting member 720 may include a subsidiary layer (not shown) for improving the luminous efficiency of the emission layer in addition to the organic emission layer that emits light. The subsidiary layer may be one or more layers selected from an electron transport layer (ETL), a hole transport layer (HTL), an electron injection layer (EIL) and a hole injection layer (HIL). The common electrode 730 is formed on the organic light emitting member 720. The common electrode 730 is made out of the transparent material of ITO or IZO, is formed on the entire surface of the substrate, and forms a pair in conjunction with the pixel electrode 710 to allow for a current to flow through the organic light emitting member 720.

A gasket 21 for sealing is formed along the circumference portion on the organic light emitting display panel 10, and the polarizing plate 30 is attached to the upper portion of the gasket 21. As a result, a vacuum portion 20 is formed between the polarizing plate 30 and the display portion of the organic light emitting display panel 10. This vacuum portion 20 prevents any external impact that may be applied to the window 40 from being relayed to the organic light emitting display panel 10.

The polarizing plate 30 includes a linear polarizing member 310 and a retardation film 320 that is disposed under the linear polarizing member 310. The linear polarizing member 310 includes a polarizer layer 312, a lower support portion 311 and an upper support portion 313 that support the polarizer layer 312. The polarizer layer 312 may be made out of PVA (Poly Vinylalcohol), and the lower support portion 311 and the upper support portion 313 may be made out of TAC (Triacetyl cellulous).

The retardation film 320 may be a λ/4 retardation film, and may convert linearly polarized light into circularly polarized light and vice versa. The retardation film 320 may be a birefringence film or an alignment film of liquid crystal polymer or a film that is supported with the alignment layer of liquid crystal polymer by stretching a film that is made out of an appropriate polymer such as polycarbonate, polyvinylalcohol, polystyrene, polymethylmethacrylate, polypropylene, polyolefine, polyarylate, or polyamide.

The polarizing plate 30 acts as a circular polarizing plate because the linear polarizing member 310 linearly polarizes light in a predetermined direction and the retardation film 320 converts the linearly polarized light into circularly polarized light.

Since the first adhesive layer 340 is formed between the linear polarizing member 310 and the window 40, the linear polarizing member 310 and the window 40 are attached to each other. Since the second adhesive layer 330 is formed between the linear polarizing member 310 and the retardation film 320, the linear polarizing member 310 and retardation film 320 are attached to each other. The first adhesive layer 340 and the second adhesive layer 330 are pressure sensitivity adhesive layers (PSAs) and are made out of a film that includes an adhesive agent, and responds to pressure that is supplied from the outside to perform the adhesion action. The first and second adhesive layers 340 and 330 may be made out of an acryl-based or rubber-based adhesive agent that has a refractive index in the range of 1.46 to 1.52, or an adhesive agent that includes particulates such as zirconia and the like in order to adjust the refractive index of the adhesive agent.

The protective film 350 is attached to the lower portion of the retardation film 320 in order to prevent the retardation film 320 from being damaged by scratches and the like. The protective film 350 may be an acetate-based resin, such as triacetylcellolose or a triacetylcellulose film in which its surface is saponificated with alkali and the like. The window 40 is made out of a transparent material, and protects the organic light emitting display panel 10.

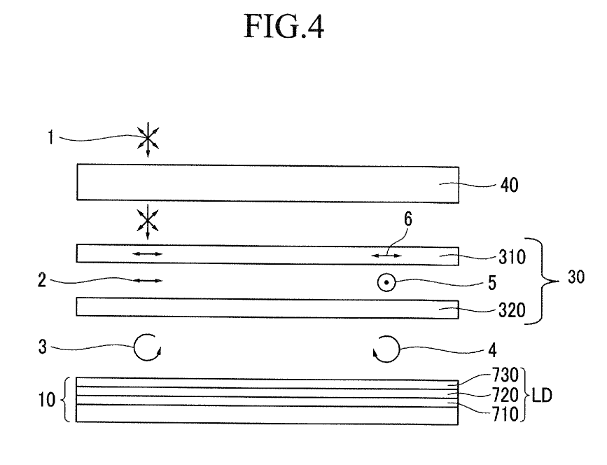

An operation principle for improving the external light visibility of the organic light emitting diode (OLED) display that is shown in FIG. 1 to FIG. 3 will be described in detail referring to FIG. 4. FIG. 4 is a schematic diagram that illustrates an operation principle of the organic light emitting diode (OLED) display of FIG. 1.

Turning now to FIG. 4, FIG. 4 is a schematic diagram that illustrates an operation principle of the organic light emitting diode (OLED) display of FIG. 4. As illustrated in FIG. 4, the external light 1 penetrates the window 40 and is incident on the polarizing plate 30. In this case, the polarizing plate 30 absorbs a portion of the external light, and linearly polarizes the remaining portion of the external light in a direction of penetration axis 6 of the polarizing plate 30. The linearly polarized external light 2 penetrates the λ/4 retardation film 320 and becomes left circularly polarized. The left circularly polarized external light 3 reflects off the reflection electrode 710 of the organic light emitting display panel 10 and becomes right circularly polarized. The right circularly polarized external light 4 penetrates the λ/4 retardation film 320 and becomes linearly polarized external light 5. In this case, since the polarization axis of the linear polarization 5 is orthogonal to the penetration axis 6 of the polarizing plate 30, the linearly polarized external light 5 is absorbed by linear polarizing member 310 of polarizing plate 30.

As described above, the gap between the window 40 and the polarizing plate 30 is removed by attaching the polarizing plate 30 to the lower portion of the window 40 and separating the polarizing plate 30 from the organic light emitting display panel 10. The external light visibility can be improved by absorbing light that is incident on the lower portion of the polarizing plate 30 by the polarizing plate 30.

In addition, in the known organic light emitting diode (OLED) display that has the window integrated structure for improving the external light visibility, since a process for injecting the adhesive agent or resin between the polarizing plate 30 of the organic light emitting display panel 10 and the window 40 may be omitted, cost reduction and process simplification may be achieved.

The following Table 1 is a comparison table for external light visibilities of the organic light emitting diode (OLED) display according to an exemplary embodiment and various organic light emitting diode (OLED) displays.

TABLE 1

| Measured | Exemplary | Comparative | Comparative | Comparative | Comparative |
|---|---|---|---|---|---|
| item | Embodiment | Example 1 | Example 2 | Example 3 | Example 4 |
| Brightness | 194.12 | 199.71 | 195.98 | 189.3 | 188.58 |
| (cd/m²) | | | | | |
| Contrast ratio | 12132.6 | 12802 | 13152.87 | 13717.39 | 11860.24 |
| Color | 109.3% | 107.8% | 109.4% | 109.1% | 106.9% |
| reproducibility | | | | | |
| Contrast ratio | 2.38 | 1.7 | 2.14 | 1.88 | 1.94 |
| under external | | | | | |
| light | | | | | |
| (10000 lux) | | | | | |
| Color | 13.1% | 5.1% | 9.8% | 6.8% | 7.6% |
| reproducibility | | | | | |
| under external | | | | | |
| light | | | | | |
| (10000 lux) | | | | | |

In Table 1, the measured values in respects to Comparative Example of various structures are shown. Comparative Example 1 has a structure in which a circularly polarizing plate that has a reflection prevention layer is attached to the upper portion of the organic light emitting display panel 10 and the window is spaced-apart from the circularly polarizing plate by a predetermined interval, and Comparative Example 2 has a structure in which a circularly polarizing plate that has a reflection prevention layer is attached to the upper portion of the organic light emitting display panel 10 and the window to which the circularly polarizing plate that has a reflection prevention layer is attached is spaced-apart from the circularly polarizing plate by a predetermined interval. In addition, Comparative Example 3 has a structure in which a circularly polarizing plate that has a reflection prevention layer is attached to the upper portion of the organic light emitting display panel 10 and the window to which the circularly polarizing plate that has a hard coating layer is attached is spaced-apart from the circularly polarizing plate by a predetermined interval, and Comparative Example 4 has a structure in which a circularly polarizing plate that has a reflection prevention layer is attached to the upper portion of the organic light emitting display panel 10 and the window to which the linearly polarizing plate that has a hard coating layer is attached is spaced-apart from the circularly polarizing plate by a predetermined interval.

As shown in Table 1, in the organic light emitting diode (OLED) display according to an exemplary embodiment, it can be seen that in the case of when the external light is 10,000 lux, the contrast ratio is 2.38, which is better than each of Comparative Examples 1 to 4. In the case of when the external light is 10,000 lux, the color reproducibility is 13.1%, which is better than each of Comparative Examples 1 to 4.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display, comprising:
an organic light emitting display panel that includes an organic light emitting member;
a polarizing plate spaced-apart from the organic light emitting display panel and arranged at an upper portion thereof; and
a window that is attached to an upper portion of the polarizing plate to protect the organic light emitting display panel.

2. The OLED display of claim 1, wherein the polarizing plate comprises:
a linear polarizing member; and
a retardation film arranged under the linear polarizing member.

3. The OLED display of claim 2, wherein the retardation film is a λ/4 retardation film.

4. The OLED display of claim 2, further comprising a first adhesive layer that is arranged between the linear polarizing member and the window.

5. The OLED display of claim 3, further comprising a second adhesive layer arranged between the linear polarizing member and the λ/4 retardation film.

6. The OLED display of claim 5, further comprising a protective film that is attached to a lower portion of the λ/4 retardation film.

7. The OLED display of claim 1, wherein the organic light emitting display panel further includes a reflection electrode.

8. The OLED display of claim 7, wherein external light is reflected off the reflection electrode and absorbed by the polarizing plate.

9. The OLED display of claim 1, the polarizing plate being in direct contact with said window.

10. The OLED display of claim 2, wherein the organic light emitting display panel further includes a reflection electrode, wherein external light is reflected off the reflection electrode and is absorbed by the polarizing plate.

11. The OLED display of claim 10, the display to allow the external light to pass through the window and the polarizing plate from an outside, reflect of the reflection electrode of the organic light emitting display panel, and then convert the external light from a circularly polarized light to a linearly polarized light by passing through the retardation film of the polarizing plate for a second time, the linearly polarized external light then being absorbed by the linear polarizing member of the polarizing plate.

12. The OLED display of claim 11, the linearly polarized external light having a polarization axis that is orthogonal to a penetration axis of the linear polarizing member of the polarizing plate after said passing through the retardation film for said second time.
